(19) United States
(12) Patent Application Publication
(10) Pub. No.: US 2007/0093089 A1
(43) Pub. Date: Apr. 26, 2007

(54) Relay-fuse system and method thereof

(76) Inventors: Douglas K. Ford, Fort Wayne, IN (US); Amit Kulkarni, Fort Wayne, IN (US)

Correspondence Address: Douglas K. Ford, 1830 Wayne Trace, Fort Wayne, IN, 46803, US

(21) Appl. No.: 11/254,566

(22) Filed: Oct. 20, 2005

(51) Int. Cl. H05K 1/00

(52) U.S. Cl. 439/76.2

(57) ABSTRACT

The present invention provides a relay-fuse system for increasing overall ampere interrupt current (AIC) rating of the relay. The relay fuse system comprises a relay having a base member configured to be connected to an electrical device; a fuse assembly mounted on the base member, the fuse assembly having a first clip and a second clip capable of electrically engaging a fuse; a fuse carrier member configured to form a receiving area for receiving the first clip, the second clip, and the fuse; and a cover member mounted on said fuse carrier member for covering the receiving area. The first clip is capable of connecting to the relay, the second clip is capable of connecting to an incoming power line thereby establishes electrical connection between the incoming power line, the relay fuse system, and the electrical device and increases overall ampere interrupt current (AIC) rating of said relay.

### FIELD OF THE INVENTION

The present invention relates to fault tolerant assemblies, and, more particularly, to a system and method of relay-fuse for handling interrupt current ratings equivalent to circuit breakers.

### BACKGROUND OF THE INVENTION

In an electric power transfer line, a circuit interrupter is required for opening and stopping an overload of electrical current due to any type of electrical fault created by man, machine, mistake or nature. Circuit breakers have been used for performing such circuit interruption functions. Relays were used as an alternative to circuit breakers, since relays were less expensive than circuit breakers and lasted for greater number of actuations than a circuit breaker. The use of relays having a lower ampere interrupt current (AIC) rating has been prohibited due to security reasons and relays with an AIC rating of less than 30000 were disallowed from installation.

The prior art related to the relays for the purpose of controlling electrical loads includes the following:

U.S. Patent Application No. 20050146824 discloses an active safety circuit with loads protected by solid state relays comprising a fuse inserted in a supply network of relays and a grounded shunt line from one point of the network between said fuse and relays, and a safety switch controlled by the microcontroller and inserted in the line. A temperature detector is either associated to each relay or is commonly shared by several of the relays, and the detector is connected to the microcontroller. This patent involves a complex configuration and does not address the issue related to the requirements/standard of National Electric Code 2002, for handling, interrupt current ratings.

U.S. Patent Application No.20040067691 discloses a pre-assembled electrical fuse relay box comprising an upper frame having an upper compartment and a first locking receiver, a plurality of electrical components pre-assembled within the upper compartment, a lower frame having a lower compartment and a second locking receiver, a plurality of connector modules pre-assembled within the lower compartment, spacers positioned within the lower compartment for locking the electrical wires, an upper cover pivotally mounted on the upper compartment, and a lower cover pivotally mounted on the lower compartment. This patent also involves a complex configuration and does not address the issue related to the requirements/standard of National Electric Code 2002, for handling interrupt current ratings.

None of the prior art discloses any system which aims to make relays compliant with the National Electric Code 2002 requirements/standards for handling interrupt current ratings equivalent to circuit breakers used in any constructed building.

Accordingly, there exists a need for an improved combination of convenient and utility, for handling interrupt current ratings equivalent to circuit breakers used in buildings, which uses a fault tolerant relay as the control point of the energy management system while remaining in compliance with the requirements of the National Electric Code 2002.

### SUMMARY OF THE INVENTION

In view of the foregoing disadvantages inherent in the above mentioned prior arts, the general purpose of the present invention is to provide a relay-fuse system which include all the advantages of the prior arts, and to overcome the abovementioned drawbacks of the prior art. The present invention provides a relay-fuse system which comprises a fuse attached to a relay, such that, the fuse is in electrical engagement with the electrical current passing through high voltage contacts of the relay and increases the over all AIC rating of the relay.

In one aspect, the present invention provides a new, simplified, and efficient relay-fuse system which provides a relay with an AIC rating for greater number of actuations and eliminates the need for circuit breaker. The relay-fuse system of the present invention can be mass produced inexpensively.

In another aspect, the present invention make the attachment of a time delay fuse with ample interrupt current ratings an integral part of the relay. Furthermore, the present invention also provides a visual indication as part of the fault tolerant relay when the fuse has blown and needs replaced

In another aspect, the present invention provides a relay-fuse system which comprises: a relay having a base member configured to be connected to an electrical device; a fuse assembly mounted on the base member and having a first clip and a second clip capable of electrically engaging a fuse; a fuse carrier member forms a receiving area for receiving the first clip, the second clip, and the fuse; and a cover member mounted on the fuse carrier member for covering the receiving area. The first clip is capable of connecting to the relay; the second clip is capable of connecting to an incoming power line and establishes electrical connection between the incoming power line, the relay fuse system, and the electrical device. The relay fuse system of the present invention increases the overall ampere interrupt current (AIC) rating of the relay.

In another aspect, the present invention provides a fuse assembly in electrical connection with a relay and an electrical device. The fuse assembly comprises: a fuse, a first clip, a second clip, a fuse carrier member, and a cover member. The fuse has a first electrical contact and a second electrical contact. The first clip has a plurality of first fuse engaging portions and a plurality of legs extending from a base portion in a direction opposite to a direction in which the first fuse engaging portion extend. The first clip further has a first clip opening for receiving a fastener. The second clip has a first base portion extending to form a second base portion, the first base portion has a pair of second fuse engaging portions extending therefrom and a connecting portion extends from the second base portion. The second fuse engaging portions and the connecting portion extends in the same direction. The second clip further has a second clip opening for receiving a fastener. The fuse carrier member configured to form a receiving area for receiving the first clip, the second clip, and the fuse; and a cover member mounted on the fuse carrier member for covering the receiving area. The first clip is capable of connecting to the relay and the second clip is capable of connecting to an incoming power line thereby establishes electrical connection between the incoming power line, the relay fuse system, and the electrical device. The fuse assembly of the present invention increases overall ampere interrupt current (AIC) rating of the relay.

In a further aspect of the present invention, a method of bringing the conductive portions of the fuse holder directly in line with the contacts of a relay and increasing the overall ampere interrupt current (AIC) rating of a relay comprises the steps of: configuring a relay-fuse system having a fuse with a first and second electrical contacts, a first clip with a plurality of first fuse engaging portions and a plurality of legs, a second clip with a second fuse engaging portion and a connection portion, a fuse carrier member with a receiving area, and a cover member; receiving the first clip and the second clip in the receiving area of the fuse carrier member; receiving a fuse in the first clip and the second clip at the first and second electrical contacts; establishing an incoming electrical connection between the incoming line to the relay-fuse system through the connecting portion of the second clip; establishing an electrical connection between the fuse and the relay through the legs of the first clip; and establishing an outgoing electrical connection between the relay-fuse assembly and the electrical device.

These together with other aspects of the present invention, along with the various features of novelty that characterize the invention, are pointed out with particularity in the claims annexed hereto and forming a part of this disclosure. For a better understanding of the invention, its operating advantages and the specific objects attained by its uses, reference should be had to the accompanying drawings and descriptive matter in which there are illustrated exemplary embodiments of the invention.

### BRIEF DESCRIPTION OF THE DRAWINGS

For a better understanding of the nature of the present invention, reference should be made in the detailed description taken in conjunction with the accompanying drawings in which:

FIG. 1 is an exploded perspective view of a fuse assembly 10, according to an exemplary embodiment of the present invention;

FIG. 1A is a perspective view of the fuse assembly 10 in an assembled state, according to an exemplary embodiment of the present invention;

FIG. 2 is a perspective view of the fuse carrier member 20, according to an exemplary embodiment of the present invention;

FIG. 3 is a perspective view of a fuse carrier member 20 with the fastened first clip 80, and a second clip 110, according to an exemplary embodiment of the present invention;

FIG. 4 is a perspective view of a fuse carrier member 20 with a fastened first clip 80, a second clip 110, and an inserted fuse 12, according to an exemplary embodiment of the present invention;

FIG. 5 is a perspective view of the back portion of the fuse career member 20, according to an exemplary embodiment of the present invention;

FIG. 6 is a perspective view of the first clip 80, according to an exemplary embodiment of the present invention; and

FIG. 7 is a perspective view of the second clip 110, according to an exemplary embodiment of the present invention.

Like reference numerals refer to like parts throughout several views of the drawings.

### DETAILED DESCRIPTION OF THE INVENTION

The exemplary embodiments described herein detail for illustrative purposes are subject to many variations in structure and design. It should be emphasized, however that the present invention is not limited to a particular relay-fuse/device system shown and described. Rather, the principles of the present invention can be used with a variety of relay-fuse device/system configurations. It is understood that various omissions, substitutions of equivalents are contemplated as circumstances may suggest or render expedient, but is intended to cover the application or implementation without departing from the spirit or scope of the claims of the present invention.

The present invention provides a new, simplified, and efficient relay-fuse system which provides a relay for greater number of actuations and eliminates the need for circuit breaker. The relay-fuse system of the present invention can be mass produced inexpensively.

The present invention make the attachment of a time delay fuse with ample interrupt current ratings an integral part of the relay and provides a method of bringing the conductive portions of the fuse holder directly in line with the contacts of a relay. Furthermore, the present invention also provides a visual indication as part of the fault tolerant relay when the fuse has blown and needs replaced.

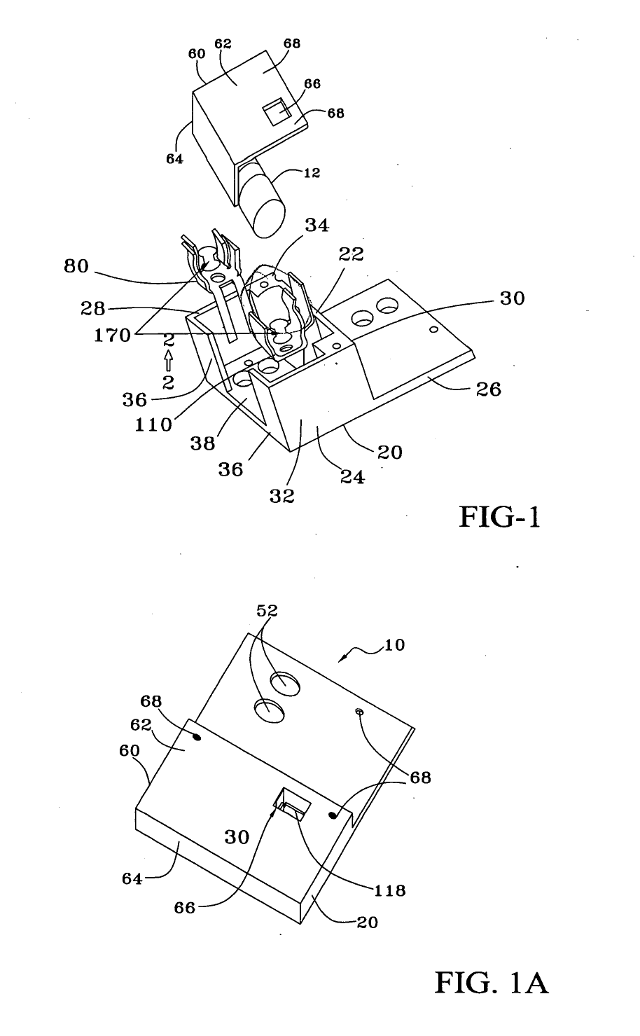

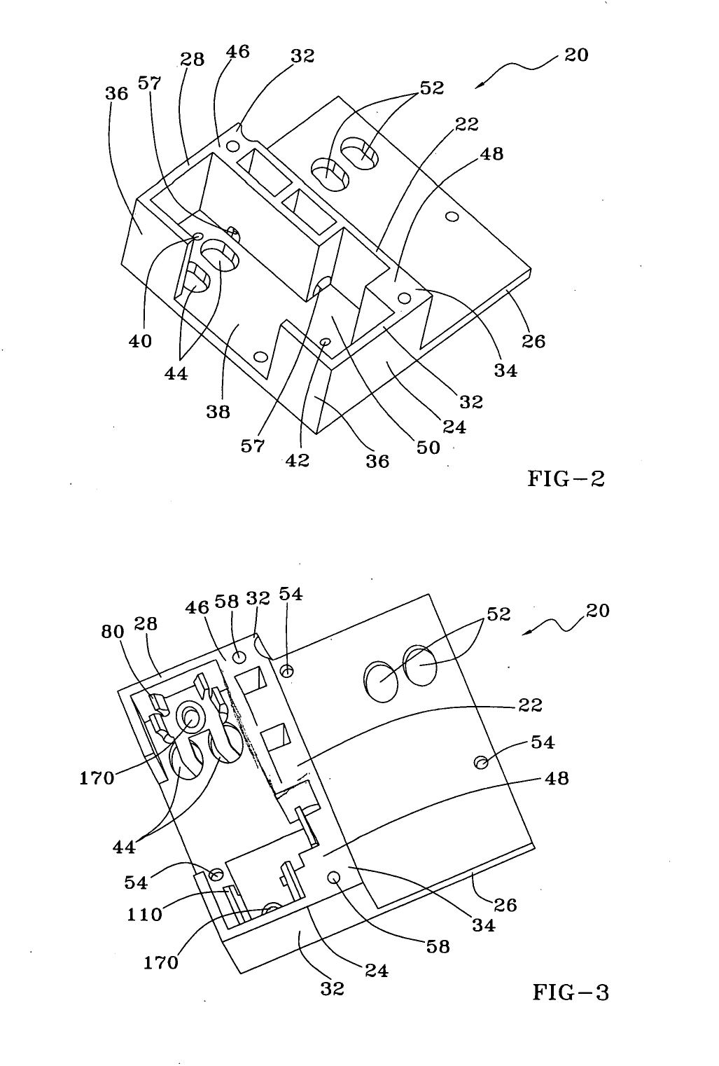

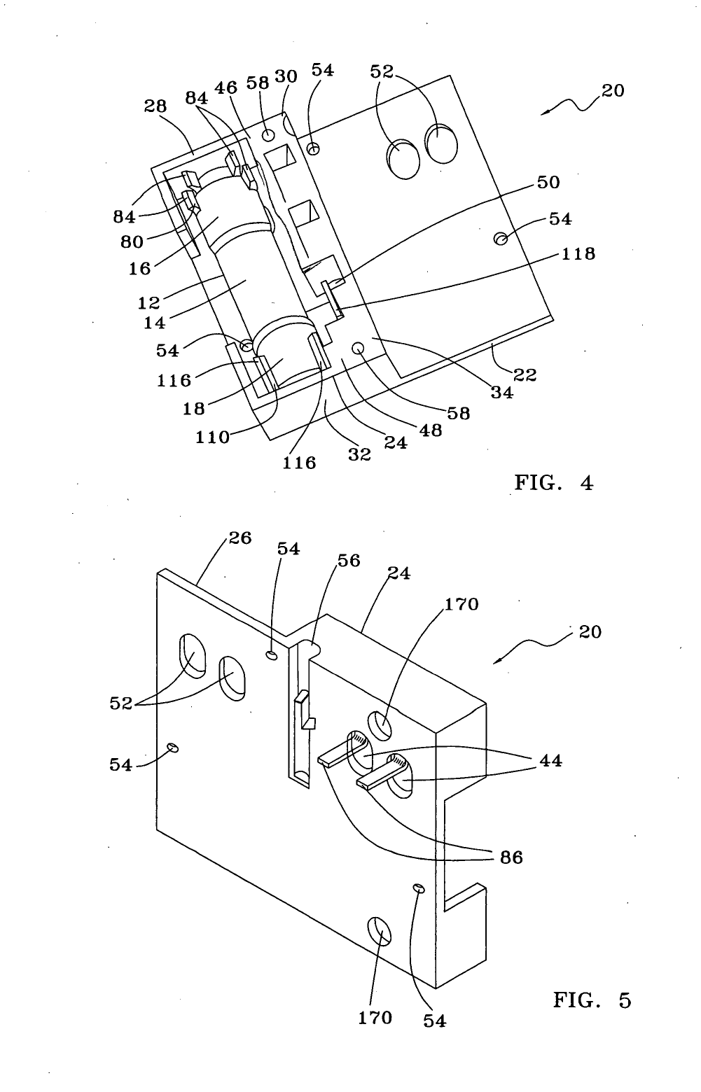

Referring now to FIGS. 1, 1A and 2, in one embodiment, a fuse assembly 10 comprises a fuse carrier member 20 capable of receiving a fuse 12, a cover member 60, a first clip 80, and a second clip 110. The fuse 12 has a substantially cylindrical geometry comprising a body portion 14, with a first electrical contact 16 and a second electrical contact 18 at each end of the body portion 14.

The fuse carrier member 20 has a geometry that is capable of securely receiving the first clip 80, the second clip 110 and the fuse 12. For example, the fuse carrier member 20 has a partition wall 22 extending in a direction of an arrow 2-2, such that, the partition wall 22 divides the fuse carrier member 20 into a first portion 24 and a second portion 26. The first portion 24 is surrounded on three sides by the partition wall 22, a first side wall 28 extending perpendicular to the partition wall 22 at a first end 30, and a second side wall 32 extending perpendicular to the partition wall 22 at a second end 34; and partially on a fourth side by side walls 36 extending perpendicular to the first side wall 28 and the second side wall 32 (i.e., side wall 36 being parallel to the partition wall 22) to form a receiving area 38 (i.e., an interior volume). The receiving area 38 has openings/recesses to enable suitable securing means, such as rivets 170, to extend through and secure a component to the receiving area 38. For example, the receiving area 38 has a first fastener opening 40 and a second fastener opening 42 (shown in FIG. 3) to receive one end of rivets 170, when riveting the first clip 80 and the second clip 110 to the fuse carrier member 20. In an additional embodiment, the securing means may also include screws, insert molding or the like.

The cover member 60 has a top portion 62 and a side portion 64 extending perpendicular to the top portion 62, such that, when the cover member 60 is disposed on the fuse carrier member 20, the top portion 62 contacts upper surfaces of the partition wall 22, first side wall 28, second side wall 32, and the side walls 36, thereby covering the receiving area from a top end. Also, in this position, the side portion 64 contacts outer surfaces of the side walls 36 to cover the receiving area 38 from a side end.

The cover member 60 further has a first pair of through holes 68 that aligns with a second pair of through holes 58 on the fuse carrier member 20, when the cover member 60 is disposed on the fuse carrier member 20, as described above. The cover member 60 is fastened to the fuse carrier member 20 by passing fasteners (e.g., bolts, nuts, screws, and the like) through the first pair of through holes 68 and the second pair through holes 58.

The first clip 80 and the second clip 110 may be fixed to the receiving area 38 of the fuse carrier member 20 using the rivets 170, screws, insert molding or the like securing means. The clips 80, 110 have geometry capable of securely receiving the fuse 12. The fuse 12 may be inserted in the receiving area 38, such that, the first electrical contact 16 engages with the first clip 80 and the second electrical contact 18 engages the second clip 110. In this position, the fuse 12 is mechanically and electrically engaged with the clips 80, 110.

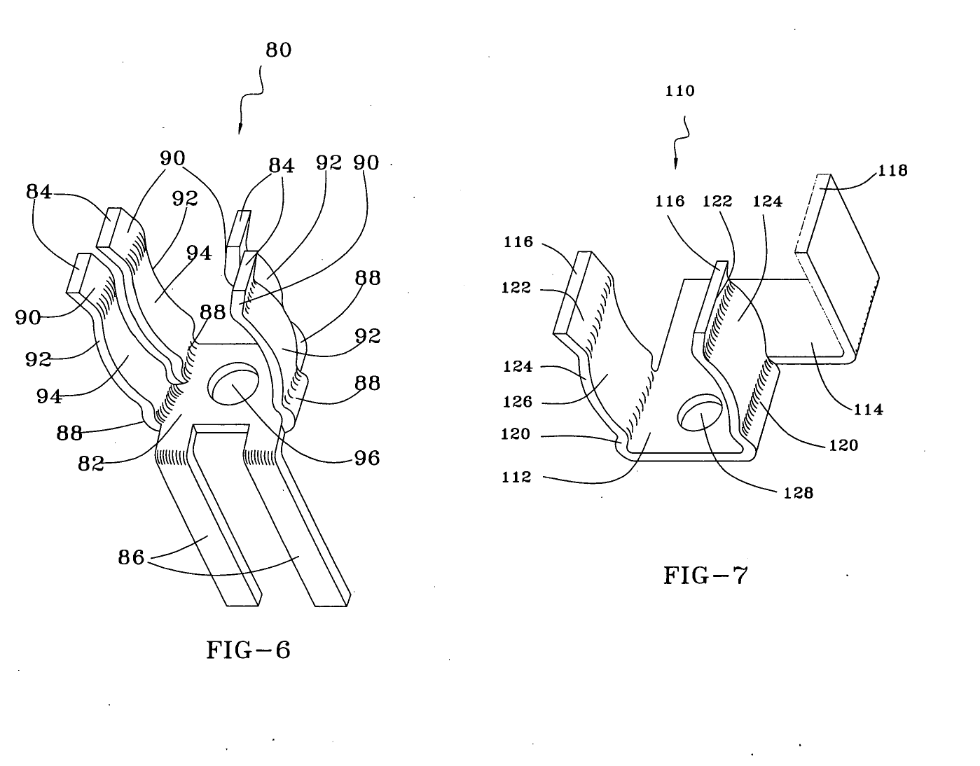

As illustrated in FIG. 6, the first clip 80 has a base portion 82; four fuse engaging portions 84, extending from the base portion 82; and two legs 86, extending from the base portion 82, in a direction opposite to a direction in which the fuse engaging portions 84 extend. The fuse engaging portions 84 have a rearward end 88 connected to the base portion 82 and a rounded forward end 90. A middle portion 92 between the rearward end 88 and the forward end 90 is curved to form a concave seat 94 for receiving the first electrical contact 16 of the fuse 12.

The first clip 80 further has a first clip opening 96 that aligns with the first fastener opening 40 when the first clip 80 is placed on the receiving area 38 of the fuse carrier member 20, such that, the fuse engaging portions 84 extend in the direction of the arrow 2-2 and the legs 86 extend out of the fuse carrier member 20 through leg openings 44 on the receiving area 38 of the fuse carrier member 20. In an exemplary embodiment, the first clip 80 may be riveted onto the receiving area 38 of the fuse carrier member 20 by passing one of the rivets 170 through the first clip opening 96 and the first fastener opening 40. However, the first clip 80 may also be secured using screws, insert molding or the like securing means.

As illustrated in FIG. 7, the second clip 110 has a first base portion 112, a second base portion 114, the first base portion 112 actually extends to form the second base portion; two fuse engaging portions 116, extending from the first base portion 112; and a connecting portion 118, extending from the second base portion 114. The fuse engaging portions 116 have a rearward end 120 connected to the first base portion 112 and a rounded forward end 122. A middle portion 124 between the rearward end 120 and the forward end 122 is curved to form a concave seat 126 for receiving the second electrical contact 18 of fuse 12.

The first portion 24 of the fuse assembly 20 has a first wall extension 46 abutting out at the first end 30 and a second wall extension 48 abutting out at second end 34, such that, a connect area 50 is formed between the first wall extension 46 and the second wall extension 48; the connect area 50 being a part of the receiving area 38. The second clip 110 further has a second clip opening 128 that aligns with the second fastener opening 42 when the second clip 110 is placed on the receiving area 38 of the fuse carrier member 20, and in this position the connect area 50 adaptively receives the second base portion 114, such that, fuse engaging portions 116 and the connecting portion 118 extend in the direction of the arrow 2-2. The second clip 110 may be riveted onto the receiving area 38 of the fuse carrier member 20 by passing one of the rivets 170 through the second clip opening 128 and the second fastener opening 42. In an additional embodiment, the second clip 110 may be secured to the receiving area 38 by screws, insert molding or the like securing means.

As described above and as illustrated in FIG. 3, the legs 86 of the first clip 80 extending out of the leg openings 44 of the fuse carrier member 20 may be received in openings on a base member of a relay (not shown), i.e., the legs 86 are inserted into brass screw terminals in the openings on the base member of the relay. This engagement assists in mounting the fuse assembly 10 to the relay. Additionally, the first portion 24 and the second portion 26 of the fuse carrier member 20 has a plurality of engagement holes 54 that may be used for mounting the fuse assembly 10 to the relay. For example, the engagement holes 54 may be configured to receive threaded screws, and the like, extending through the engagement holes 54 and similar engagement means on the base member of the relay.

The top portion 62 of the cover member 60 further comprises a rectangular opening 66, such that, when the cover member 60 is disposed on the fuse carrier member 20, the connect area 50 with the extended connecting portion 118 is exposed, as illustrated in an assembled state of the fuse assembly 10 in FIG. 1A. In this exposed state, a field wire (not shown) of an electrical device (e.g., a lighting load) may be connected to the connecting portion 118 to establish an incoming electrical connection between the relay-fuse device and the electrical device through the fuse 12, more specifically, a flag terminal (not shown) is crimped onto an end of the field wire, and then slid onto the connecting portion 118. Also, a wire (not shown) of the relay comes out of wire openings 52 on the second portion 26 to be connected on connecting terminals on the electrical device, to establish an outgoing electrical connection between the relay-fuse device and the electrical device.

In such systems, as described above, wherein the fuse assembly 10 is mounted on the base member of the relay, the fuse 12 comes in direct conductive line with an electrical current passing through high voltage contacts of the relay, and thereby resulting in relay-fuse devices having high AIC ratings.

Optionally, fuse assembly 10 has a visual indicator (not shown) in operative communication with the fuse 12 for confirming whether the fuse 12 has blown out or not. The visual indicator may be a light emitting diode (LED) that is ON when associated fuse 12 is blown and OFF when the fuse 12 is capable of conducting current. Such a visual indicator may provide an indication of fuse condition to someone who might view the fuse assembly 10 at a substantial distance from it. The fuse carrier member 20 has a visual indicator housing 56 to receive the visual indicator, as illustrated in FIG. 3. Also, the first wall extension 46 has a plurality of recesses (not shown) such that extensions of the visual indicator (e.g., legs of the LED) may be attached to the fuse clips 80, 110.

The cover member 20 and the fuse carrier member 40 may be molded out of an insulative material such as plastic or epoxy, although other formation techniques and materials may be employed. The fuse clips 80, 100 are made of conductive materials such as metals or the like.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is understood that various omissions, substitutions of equivalents are contemplated as circumstance may suggest or render expedient, but is intended to cover the application or implementation without departing from the spirit or scope of the claims of the present invention.

What is claimed is:

1. A relay-fuse system, comprising:
a relay having a base member configured to be connected to an electrical device;
a fuse assembly mounted on said base member, said fuse assembly having a first clip and a second clip capable of electrically engaging a fuse;
a fuse carrier member configured to form a receiving area for receiving said first clip, said second clip, and a fuse; and
a cover member mounted on said fuse carrier member for covering said receiving area;
said first clip is capable of connecting to said relay, said second clip is capable of connecting to an incoming power line thereby establishes electrical connection between said incoming power line, said relay fuse system, and said electrical device and increases overall ampere interrupt current (AIC) rating of said relay.

2. The relay-fuse system of claim 1, wherein said first clip and said second clip have clip openings that align with openings on said receiving area, and wherein fasteners are passed through said openings for securing said first and said second clips to said fuse carrier member.

3. The relay-fuse system of claim 2, wherein said fasteners may include rivets, screws, insert molding or the like.

4. The relay-fuse system of claim 1, wherein the fuse comprises a first electrical contact and a second electrical contact.

5. The relay-fuse system of claim 1, wherein said first clip comprises four fuse engaging portions extending from a base portion of said first clip for engaging said first electrical contact of the fuse.

6. The relay-fuse system of claim 5, wherein said first clip further comprises two legs extending from said base portion of said first clip, in a direction opposite to a direction in which said fuse engaging portions extend.

7. The relay-fuse system of claim 6, wherein said legs extend out through leg openings on said receiving area of said fuse carrier member to be received in openings on said base member of said relay.

8. The relay-fuse system of claim 1, wherein said second clip has a first base portion extending to form a second base portion and a pair of fuse engaging portions extending form said first base portion for engaging said second electrical contact of the fuse.

9. The relay-fuse system of claim 8, wherein said second clip further comprises a connecting portion extending from said second base portion, said connecting portion extends in same direction as said fuse engaging portions.

10. The relay-fuse system of claim 1, wherein said cover member has an opening capable of allowing said connecting portion of said second clip to be exposed through said opening for establishing an electrical connection between said incoming power line and said relay fuse system.

12. The relay-fuse system of claim 1, wherein said fuse carrier member comprises at least an opening configured to allow wires for establishing an outgoing electrical connection between said relay-fuse system and said electrical device.

13. A fuse assembly in electrical connection with a relay and an electrical device, comprising:
a first clip having a plurality of first fuse engaging portions and a plurality of legs extending from a base portion, said plurality of legs extends in a direction opposite to a direction in which said first fuse engaging portion extend, said first clip further having a first clip opening for receiving a fastener;
a second clip having a first base portion extending to form a second base portion, said first base portion having a pair of second fuse engaging portions extending therefrom, a connecting portion extending from said second base portion, said second fuse engaging portions and said connecting portion extends in a same direction, said second clip further having a second clip opening for receiving a fastener;
a fuse carrier member configured to form a receiving area for receiving said first clip, said second clip, and a fuse; and
a cover member mounted on said fuse carrier member for covering said receiving area;
said first clip is capable of connecting to said relay, said second clip is capable of connecting to an incoming power line thereby establishes electrical connection between said incoming power line, said relay fuse system, said electrical device and increases overall ampere interrupt current (AIC) rating of said relay.

14. The fuse assembly of claim 13, wherein said first clip opening of said first clip and said second clip opening of said second clip align with first and second fastener openings on said receiving area for securing said first and said second clips to said fuse carrier member.

15. The fuse assembly of claim 14, wherein said fasteners include rivets, screws, insert molding or the like.

16. The fuse assembly of claim 13, wherein said legs extend out through leg openings on said receiving area of said fuse carrier member to be received in openings on said base member of said relay.

17. The fuse assembly of claim 13, wherein said cover member has an opening capable of allowing said connecting portion of said second clip to be exposed through said opening for establishing an electrical connection between an incoming power line and said fuse assembly.

18. The fuse assembly of claim 13, wherein said fuse carrier member comprises at least an opening configured to allow wires for establishing an outgoing electrical connection between said fuse assembly and said electrical device.

19. A method of increasing an overall ampere interrupt current (AIC) rating of a relay by establishing an electrical connection between an incoming power line, a relay-fuse assembly, and an electrical device, the method comprising:
configuring a relay-fuse system having a first clip with a plurality of first fuse engaging portions and a plurality of legs, a second clip with a second fuse engaging portion and a connection portion, a fuse carrier member with a receiving area, and a cover member;
receiving said first clip and said second clip in said receiving area of said fuse carrier member;
receiving a fuse in said first clip and said second clip;
establishing an incoming electrical connection between said incoming line to said relay-fuse system through said connecting portion of said second clip;
establishing an electrical connection between the fuse and said relay through said legs of said first clip; and
establishing an outgoing electrical connection between said relay-fuse assembly and said electrical device
